(19) United States
(12) Patent Application Publication
(10) Pub. No.: US 2026/0341647 A1
(43) Pub. Date: Oct. 29, 2026

(54) CONTROL METHOD AND PLASMA PROCESSING APPARATUS

(71) Applicant: Tokyo Electron Limited, Tokyo (JP)

(72) Inventors: Kyosuke ABE, Miyagi (JP); Keigo TOYODA, Hsin-chu (TW)

(21) Appl. No.: 19/702,329

(22) Filed: Jun. 9, 2026

Related U.S. Application Data
(63) Continuation of application No. PCT/JP2024/043888, filed on Dec. 11, 2024.

(30) Foreign Application Priority Data
Dec. 18, 2023 (JP) 2023-212650

(51) Int. Cl. H01J 37/32

(52) U.S. Cl. CPC H01J 37/32642; H01J 37/3211; H01J 37/32807; H01J 2237/334

(57) ABSTRACT

A plasma processing apparatus includes: a plasma-processing chamber; a substrate support that is disposed inside the plasma-processing chamber and includes a main body including a central region configured to support a substrate and an annular region surrounding the central region; an edge ring disposed on the annular region of the main body of the substrate support; a lifter that includes two or more support pins and an actuator, and is configured to lift and lower the edge ring; and a controller including a memory and a processor coupled to the memory, wherein the memory contains instructions, which when executed by the processor, cause the plasma processing apparatus to perform a process including: measuring consumption of the edge ring; and controlling the lifter to lower the edge ring based on the consumption of the edge ring.

### CROSS-REFERENCE TO RELATED APPLICATIONS

This application is a continuation application of International Application No. PCT/JP2024/043888, filed on Dec. 11, 2024, and designated the U.S., which is based upon and claims priority to Japanese Patent Application No. 2023-212650, filed on Dec. 18, 2023, the entire contents of which are incorporated herein by reference.

### BACKGROUND

### 1. Field of the Invention

The present disclosure relates to a control method and a plasma processing apparatus.

### 2. Description of the Related Art

For example, Japanese Unexamined Patent Application Publication No. 2019-201085 proposes a method in which a plurality of lifter pins are independently driven to be raised and lowered to control the inclination of an edge ring in the circumferential direction, thereby adjusting a height of a sheath. According to the proposed method, a variation in an etching rate is eliminated, and a recess etching shape is maintained to be vertical.

Japanese Unexamined Patent Application Publication No. 2020-113753 proposes that a second annular portion is moved upward using a sheath adjustor according to consumption of an edge ring so that a position of an upper surface of the second annular portion in the vertical direction matches a position of an upper surface of a substrate on an electrostatic chuck in the vertical direction. According to the above proposal, the position of the upper end of the sheath above the edge ring in the vertical direction is adjusted, and a difference between an etching rate at an edge of a substrate and an etching rate at an inner position of the substrate with respect to the edge of U.S. Pat. No. 11,393,710 proposes that a position of an edge ring is moved from a first position to a second position higher than the first position according to consumption of the edge ring, thereby keeping the edge ring and a sheath on the substrate parallel. International Publication No. WO 2021/026110 proposes a movable edge ring for a substrate processing system, in which a variation in capacitance is reduced.

### SUMMARY

According to one aspect of the present disclosure, there is provided a plasma processing apparatus including: a plasma-processing chamber; a substrate support that is disposed inside the plasma-processing chamber and includes a main body including a central region configured to support a substrate and an annular region surrounding the central region; an edge ring disposed on the annular region of the main body of the substrate support; a lifter that includes two or more support pins and an actuator, and is configured to lift and lower the edge ring; and a controller including a memory and a processor coupled to the memory, wherein the memory contains instructions, which when executed by the processor, cause the plasma processing apparatus to perform a process including: measuring consumption of the edge ring; and controlling the lifter to lower the edge ring based on the consumption of the edge ring.

### BRIEF DESCRIPTION OF THE DRAWINGS

FIG. 1 is a diagram illustrating one example of a plasma processing system according to one embodiment;

FIG. 2A is a diagram for explaining a relationship between an incident angle of ions and a frequency of bias radio frequency (RF) power in one example of operation of an edge ring;

FIG. 2B is a diagram for explaining the relationship between the incident angle of ions and the frequency of the bias RF power in one example of the operation of the edge ring;

FIG. 2C is a diagram for explaining a relationship between an incident angle of ions and a frequency of bias RF power in one example of operation of the edge ring;

FIG. 2D is a diagram for explaining the relationship between the incident angle of ions and the frequency of the bias RF power in one example of the operation of the edge ring;

FIG. 3A is a diagram for explaining a relationship between an incident angle of ions and a shape of the edge ring in one example of operation of the edge ring;

FIG. 3B is a diagram for explaining the relationship between the incident angle of ions and the shape of the edge ring in one example of the operation of the edge ring;

FIG. 4 is a flowchart illustrating one example of an edge ring control method according to one embodiment;

FIG. 5A is a diagram for explaining the edge ring control method according to one embodiment;

FIG. 5B is a diagram for explaining the edge ring control method according to one embodiment;

FIG. 6A is a diagram illustrating an experiment result of the edge ring control method according to one embodiment;

FIG. 6B is a diagram illustrating the experiment result of the edge ring control method according to one embodiment;

FIG. 6C is a diagram illustrating the experiment result of the edge ring control method according to one embodiment; and

FIG. 6D is a graph illustrating the experiment result of the edge ring control method according to one embodiment.

### DETAILED DESCRIPTION OF THE DISCLOSURE

According to the present disclosure, there is provided a control method and a plasma processing apparatus, which improve control precision of an incident angle of ions incident in an edge region of a substrate.

Hereinafter, embodiments of the present disclosure will be described with reference to drawings. In the drawings, the same constituent components are denoted by the same reference numerals, and redundant description may be omitted.

### Plasma Processing System

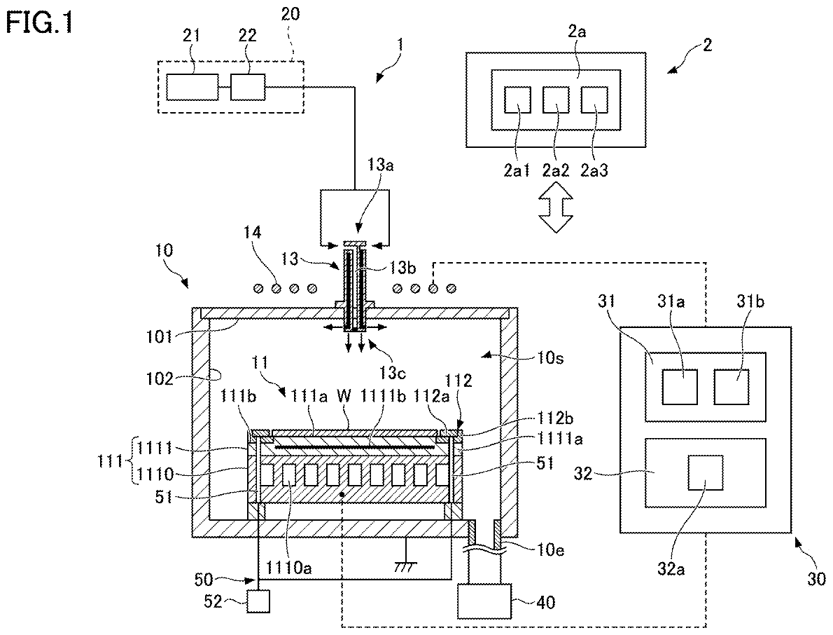

A configuration example of a plasma processing system will be described hereinafter. FIG. 1 is a diagram for explaining a configuration example of an inductively coupled plasma processing apparatus.

The plasma processing system includes the inductively coupled plasma processing apparatus 1 and a controller 2. The inductively coupled plasma processing apparatus 1 includes a plasma-processing chamber 10, a gas supply 20, a power supply 30, an exhaust system 40, and a lifter 50. The plasma-processing chamber 10 includes a dielectric window. The plasma processing apparatus 1 includes a substrate support 11, a gas introduction portion, and an antenna 14. The substrate support 11 is disposed inside the plasma-processing chamber 10. The antenna 14 is disposed above or at an upper portion of the plasma-processing chamber 10 (i.e., on or above the dielectric window 101). The plasma-processing chamber 10 has a plasma-processing space 10s defined by the dielectric window 101, side walls 102 of the plasma-processing chamber 10, and the substrate support 11. The plasma-processing chamber 10 includes at least one gas supply port configured to supply at least one process gas to the plasma-processing space 10s, and at least one gas discharge port configured to discharge the gas from the plasma-processing space 10s. The plasma-processing chamber 10 is grounded.

The substrate support 11 includes a main body 111. The main body 111 includes a central region 111a configured to support a substrate W, and an annular region 111b configured to support a ring assembly 112. A wafer is an example of the substrate W. The annular region 111b of the main body 111 surrounds the central region 111a of the main body 111 in a plan view. A substrate W is disposed on the central region 111a of the main body 111. The ring assembly 112 is disposed on the annular region 111b of the main body 111 so that the ring assembly 112 surrounds the substrate W on the central region 111a of the main body 111. Accordingly, the central region 111a is also referred to as a substrate support surface for supporting the substrate W, and the annular region 111b is also referred to as a ring support surface for supporting the ring assembly 112.

In one embodiment, the main body 111 includes a base 1110 and an electrostatic chuck 1111. The base 1110 includes a conductive member. The conductive member of the base 1110 may function as a bias electrode. The electrostatic chuck 1111 is disposed on the base 1110. The electrostatic chuck 1111 includes a ceramic member 1111a and an electrostatic electrode 1111b disposed inside the ceramic member 1111a. The ceramic member 1111a has a central region 111a. In one embodiment, the ceramic member 1111a also has an annular region 111b. Another member surrounding the electrostatic chuck 1111, such as an annular electrostatic chuck or an annular insulating member, may have an annular region 111b. In this case, the ring assembly 112 may be disposed on the annular electrostatic chuck or the annular insulating member, or may be disposed on both the electrostatic chuck 1111 and the annular insulating member. Further, at least one RF/DC electrode, which is coupled to a below-described radio frequency (RF) power supply 31 or direct current (DC) power supply 32, or both, may be disposed inside the ceramic member 1111a. In this case, at least one RF/DC electrode functions as a bias electrode. In this case, at least one RF/DC electrode functions as a bias electrode. The conductive member of the base 1110 and at least one RF/DC electrode may function as bias electrodes. Further, the electrostatic electrode 1111b may function as a bias electrode. Therefore, the substrate support 11 includes at least one bias electrode.

The ring assembly 112 includes one or more annular members. In one embodiment, one or more annular members include one or more edge rings and at least one cover ring. The edge ring is formed of a conductive material or an insulating material. The cover ring is formed of an insulating material.

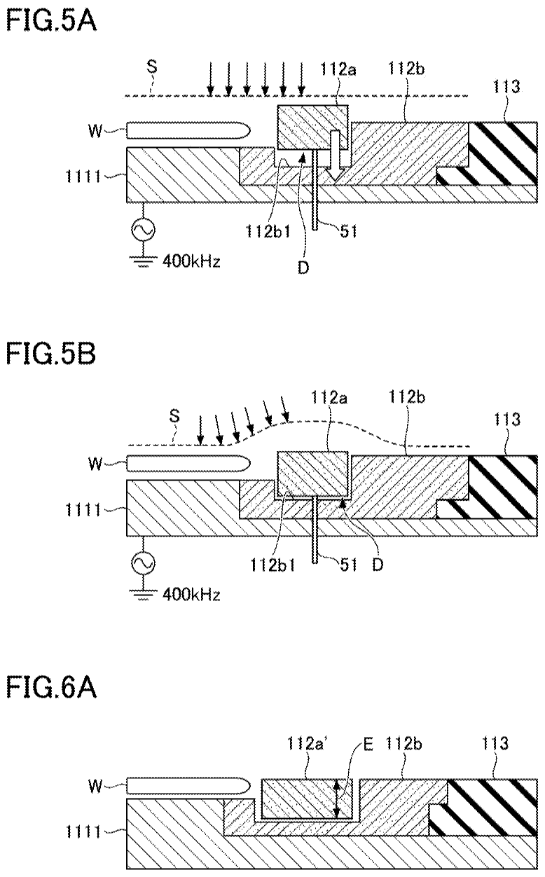

In one embodiment, the ring assembly 112 includes a first ring 112a that can be raised and lowered, a second ring 112b that supports the first ring 112a, and a cover ring 113 (see FIGS. 5A and 5B). The first ring 112a is disposed on a recess formed in the second ring 112b, and can be raised and lowered. The clearance (gap D) between the bottom surface 112b1 of the recess formed in the second ring 112b and the first ring 112a is changed by lifting or lowering the first ring 112a. The first ring 112a is supported by the second ring 112b, and the inner circumferential surface of the first ring 112a surrounds the perimeter of the substrate W. The outer circumferential surface of the first ring 112a is covered by the second ring 112b.

The first ring 112a and the second ring 112b may be formed of SiC, Si, or quartz. The cover ring 113 may be formed of quartz. In the present specification, the first ring 112a and the second ring 112b may be collectively referred to as an edge ring. The edge ring is also referred to as a focus ring. The edge ring may not be divided into the first ring 112a and the second ring 112b, and may be configured as an integrated member. The edge ring may be divided into three or more parts.

Referring back to FIG. 1, the lifter 50 lifts and lowers the first ring 112a. The lifter 50 includes two or more support pins 51 and an actuator 52. Although only two support pins 51 are illustrated FIG. 1, three or more support pins 51 are provided as the lifter 50. Each support pin 51 is formed into a cylindrical shape (with a solid core). Each support pin 51 is inserted into a through hole formed in the base 1110, a through hole formed in the electrostatic chuck 1111, and a through hole formed in the second ring 112b so that each support pin 51 can be projected and withdrawn from the bottom surface 112b1 of the recess of the second ring 112b (see FIGS. 5A and 5B).

In the case of an integral edge ring, each support pin 51 is inserted into a through hole formed in the base 1110 and a through hole formed in the electrostatic chuck 1111 so that each pin 51 can be projected and withdrawn from the ring support surface of the electrostatic chuck 1111.

The actuator 52 causes the two or more support pins 51 to be raised or lowered. As the actuator 52, for example, a motor (e.g., a DC motor, a stepping motor, a linear motor, etc.), an air drive mechanism (e.g., an air cylinder, etc.), a piezoelectric actuator, or the like can be used. As described later, the lifter 50 lowers the two or more support pins 51 according to consumption of the first ring 112a.

The substrate support 11 may include a temperature control module configured to adjust at least one of the temperature of the electrostatic chuck 1111, the temperature of the ring assembly 112, and the temperature of the substrate to a target temperature. The temperature control module may include a heater, a heat transfer medium, a flow path 1110a, or any combination of the foregoing. A heat transfer fluid, such as a brine or a gas, flows through the flow path 1110a. In one embodiment, the flow path 1110a is formed in the base 1110, and one or more heaters are disposed inside the ceramic member 1111a of the electrostatic chuck 1111. In addition, the substrate support 11 may include a heat transfer gas supply configured to supply a heat transfer gas to the space between the back surface of the substrate W and the central region 111a.

The gas introduction portion is configured to introduce at least one process gas from the gas supply 20 into the plasma-processing space 10s. In one embodiment, the gas introduction portion includes a center gas injector (CGI) 13. The center gas injector 13 is arranged above the substrate support 11, and is attached to a central opening formed in the dielectric window 101. The center gas injector 13 include at least one gas supply port 13a, at least one gas flow path 13b, and at least one gas inlet 13c. The process gas supplied to the gas supply port 13a passes through the gas flow path 13b, and is introduced into the plasma-processing space 10s from the gas inlet 13c. In addition to or instead of the center gas injector 13, the gas introduction portion may include one or more side gas injectors (SGI) attached to one or more openings formed in the side wall 102.

The gas supply 20 may include at least one gas source 21 and at least one flow rate controller 22. In one embodiment, the gas supply 20 is configured to supply at least one process gas from a respective gas source 21 to the gas introduction portion via a respective flow rate controller 22. Each flow rate controller 22 may include, for example, a mass flow controller or a pressure-control flow rate controller. Further, the gas supply 20 may include one or more flow rate modulation devices that modulate or pulse a flow rate of at least one process gas.

The power supply 30 includes an RF power supply 31 coupled to the plasma-processing chamber 10 via at least one impedance matching circuit. The RF power supply 31 is configured to supply at least one RF signal (RF power) to at least one bias electrode and the antenna 14. Thus, plasma is formed using at least one process gas supplied to the plasma-processing space 10s. Therefore, the RF power supply 31 can function as at least part of a plasma generator configured to form plasma using one or more process gases in the plasma-processing chamber 10. By supplying the bias RF signal to at least one bias electrode, a bias potential is generated in the substrate W, and ions in the formed plasma can be drawn to the substrate W.

In one embodiment, the RF power supply 31 includes a first RF generator 31a and a second RF generator 31b. The first RF generator 31a (source RF power supply) is coupled to the antenna 14, and is configured to generate a source RF signal (source RF power) for plasma formation via at least one impedance matching circuit. In one embodiment, the source RF signal has a frequence of 13 MHz or higher and 150 MHz or lower. The source RF signal (source RF power) preferably has a frequency of 13 MHz or higher. In one embodiment, the first RF generator 31a may be configured to generate multiple source RF signals having mutually different frequencies. The generated one or more source RF signals are applied to the antenna 14.

The second RF generator 31b (bias RF power supply) is coupled to at least one bias electrode via at least one impedance matching circuit, and is configured to generate a bias RF signal (bias RF power). The frequency of the bias RF signal may be the same or different from the frequency of the source RF signal. In one embodiment, the bias RF signal has a lower frequency than the frequency of the source RF signal. In one embodiment, the bias RF signal has a frequency of 100 kHz or higher and lower than 13 MHz. The bias RF signal (bias RF power) preferably has a frequency of lower than 13 MHz. In one embodiment, the second RF generator 31b may be configured to generate multiple bias RF signals having mutually different frequencies. The generated one or more bias RF signals are applied to at least one bias electrode. In various embodiments, the source RF signal or the bias RF signal, or both the source RF signal and the bias RF signal may be pulsed.

Further, the power supply 30 may include a DC power supply 32 coupled to the plasma-processing chamber 10. The DC power supply 32 includes a bias DC generator 32a. In one embodiment, the bias DC generator 32a is coupled to at least one bias electrode, and is configured to generate a bias DC signal. The generated bias DC signal is applied to at least one bias electrode.

In various embodiments, the bias DC signal may be pulsed. In this case, a sequence of voltage pulses is applied to at least one bias electrode. The voltage pulses may have a pulse waveform of rectangular shapes, trapezoidal shapes, triangular shapes, or any combination of the foregoing. In one embodiment, a waveform generator for generating a sequence of voltage pulses from the DC signal is coupled to and arranged between the bias DC generator 32a and at least one bias electrode. Accordingly, the bias DC generator 32a and the waveform generator constitute a voltage pulse generator. The voltage pulse may have a positive polarity or a negative polarity. The sequence of voltage pulses may include one or more positive voltage pulses and one or more negative voltage pulses per cycle. The bias DC generator 32a may be provided in addition to the RF power supply 31, or may be provided instead of the second RF generator 31b.

The antenna 14 includes one or more coils. In one embodiment, the antenna 14 may include an outer coil and an inner coil that are coaxially arranged. In this case, the RF power supply 31 may be coupled to both the outer coil and the inner coil, or may be coupled to either the outer coil or the inner coil. In the former case, the same RF generator may be coupled to both the outer coil and the inner coil, or separate RF generators may be coupled to the outer coil and the inner coil, respectively.

The exhaust system 40 may be coupled to, for example, the gas discharge port 10e provided at the bottom of the plasma-processing chamber 10. The exhaust system 40 may include a pressure control valve and a vacuum pump. The pressure inside the plasma-processing space 10s is adjusted by the pressure control valve. The vacuum pump may include a turbomolecular pump, a dry pump, or a combination of the foregoing.

The controller 2 processes computer-executable instructions for causing the plasma processing apparatus 1 to execute various steps described in the present disclosure. The controller 2 may be configured to control constituent components of the plasma processing apparatus 1 to execute various steps described herein. In one embodiment, a part of the controller 2 or the entire controller 2 may be included in the plasma processing apparatus 1. The controller 2 may include a processor 2a1, a memory 2a2, and a communication interface 2a3. The controller 2 is implemented, for example, by a computer 2a. The processor 2a1 may be configured to load a program from the memory 2a2, and to execute the loaded program to perform various control actions. The program may be stored in the memory 2a2 in advance, or may be acquired via a medium when necessary. The acquired program is stored in the memory 2a2. The program is then loaded from the memory 2a2, and is executed by the processor 2a1. The medium may be any of various recording media readable by the computer 2a, or may be a communication line connected to the communication interface 2a3. The processor 2a1 may be a central processing unit (CPU). The memory 2a2 may include a random access memory (RAM), a read only memory (ROM), a hard disk drive (HDD), a solid state drive (SSD), or any combination of the foregoing. The communication interface 2a3 may communicate with the plasma processing apparatus 1 via a communication line, such as a local area network (LAN).

### Incident Angle of Ions

The edge ring (the first ring 112a and the second ring 112b) is exposed to plasma during processing of a substrate W and is consumed, thereby reducing the thickness of the edge ring. Since the edge ring is consumed, the potential of the edge ring drops, and the height of the sheath above the edge ring becomes lower than the sheath above the substrate W. As a result, an incident angle of ions incident in the edge region of the substrate W is inclined inward (in the inner direction) in the radial direction of the substrate W with respect to the vertical direction of the substrate W due to the height difference formed in the sheath. The edge region of the substrate W is an outermost peripheral region of the substrate W. As one example, the edge region is a region within approximately 147 mm to the 150 mm (the outer circumferential edge of the substrate W) from the center of the substrate W in the radial direction.

By elevating the height of the edge ring to elevate the height of the sheath above the edge ring, thereby compensating reduction in the height of sheath due to the consumption of the edge ring, the incident angle of ions inclined inward can be controlled to incline outward (in the outer direction). Thus, ions are allowed to incident on the substrate W in the vertical direction by eliminating the inclination of the incident angle of ions so that a vertical etching shape can be achieved.

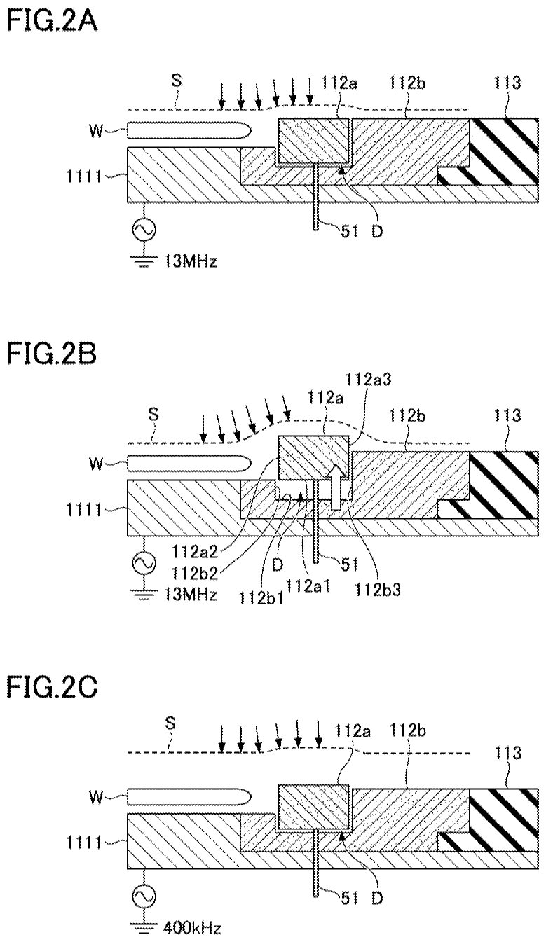

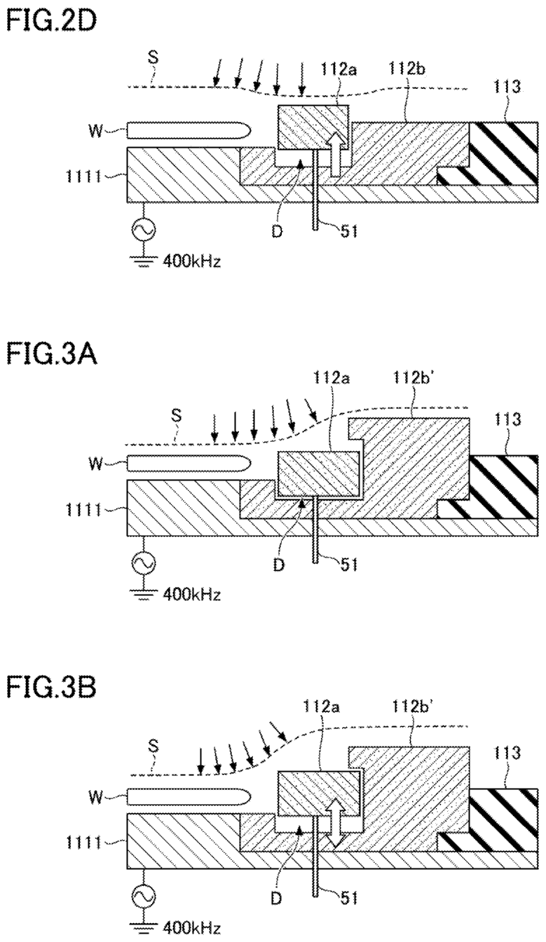

FIGS. 2A to 2D are diagrams for explaining the relationship between the incident angle of ions and the frequency of the bias RF power in one example of the operation of the edge ring. For example, in FIGS. 2A and 2B, the height of the sheath S above the first ring 112a is raised by lifting the first ring 112a based on the consumption of the edge ring. As a result, the incident angle of ions in the edge region of the substrate W is controlled to incline outward (in the outer direction) as illustrated by the arrows in FIG. 2B. In the present specification, the second ring 112b is fixed.

In the example of FIGS. 2A and 2B, the bias RF power having a frequency of 13 MHz is applied to the substrate support 11 (base 1110). On the other hand, in the example of FIGS. 2C and 2D, the bias RF power having a frequency of 400 kHz is applied to the substrate support 11 (base 1110). In FIGS. 2A and 2C, the first ring 112a is in an initial state in which the first ring 112a has not been consumed, and the first ring 112a is arranged at the lowest position. In FIGS. 2B and 2D, the first ring 112a is in a state in which the first ring 112a is raised to the same height by the support pins 51.

There is the gap D between the first ring 112a and the second ring 112b so that the first ring 112a and the second ring 112b are not in contact with each other. The gap D is a gap formed by the bottom surface (lower surface 112a1), the inner circumferential surface 112a2, and the outer circumferential surface 112a3 of the first ring 112a and an inner surface (the bottom surface 112b1, the inner surface 112b2, and the outer surface 112b3) of the recess formed in the second ring 112b when the first ring 112a is raised. Thus, a sudden change in the potential of the first ring 112a caused by the contact between the first ring 112a and the second ring 112b is avoided, thereby avoiding any adverse effect on controllability (control precision) of the incident angle of ions.

The impedance to the RF current due to the gap D varies according to the frequency. When the RF power having a frequency of 400 kHz is applied, the impedance due to the gap D becomes larger than the impedance when the RF power having a frequency of 13 MHz is applied. Therefore, the potential of the first ring 112a decreases with respect to the potential of the second ring 112b. In addition, the potential of the first ring 112a decreases as the gap D increases. As a result, when the bias RF power of 400 kHz is applied, a change in the potential of the first ring 112a when the first ring 112a is raised becomes large compared to the change in the potential of the first ring 112a when the bias RF power of 13 MHz is applied. The gap D increases, as the first ring 112a is raised more, and therefore the potential of the first ring 112a becomes even lower. As the potential difference between the plasma and the first ring 112a increases, the thickness of the sheath increases. Therefore, when the plasma is regarded as the ground, the potential difference between the plasma and the first ring 112a decreases as the potential of the first ring 112a decreases, and therefore the sheath becomes thinner. Accordingly, as the first ring 112a is raised higher, the sheath drops down above the first ring 112a, and ions are incident with the inward inclination (in the inner direction).

For example, in FIG. 2A, the potential of the second ring 112b is set to be a “high” level. When the bias RF power of 13 MHz is applied, the impedance due to the gap D is small, and the potential difference between the first ring 112a and the second ring 112b is small. Therefore, the potential of the first ring 112a is at a “high” level in FIG. 2A. As the first ring 112a is raised, the gap D increases. However, the change in the potential of the first ring 112a is small with the bias RF power of a high frequency, e.g., approximately 13 MHz, and therefore the potential of the first ring 112a of FIG. 2B is at a “high” level.

Accordingly, also in the state of FIG. 2B, the potential difference between the plasma and the first ring 112a is large similarly to the initial state of FIG. 2A. As described above, the thickness of the sheath is determined by the potential difference between the plasma and the edge ring, and the thickness of the sheath increases as the potential difference between the plasma and the edge ring increases. Therefore, when the bias RF power of 13 MHz is applied, the thickness of the sheath is hardly changed by lifting the first ring 112a, and the height of the sheath increases according to the height of the first ring 112a (the height position of the upper surface of the first ring 112a). As a result, when the bias RF power of 13 MHz is applied, ions are incident in the edge region of the substrate W with the outward inclination, as the first ring 112a is raised higher, as illustrated by the arrows of FIG. 2B.

On the other hand, when the bias RF power of 400 kHz is applied, the impedance due to the gap D is large. Therefore, when the potential of the second ring 112b is set to be a “high” level in the initial state of FIG. 2C, the potential of the first ring 112a is lowered to, for example, a “medium” level. As the first ring 112a is raised, the impedance due to the gap D further increases. Since the change in the potential of the first ring 112a is large, the potential of the first ring 112a further decreases when the first ring 112a is raised. The potential of the first ring 112a illustrated in FIG. 2D is, for example, at a “low” level.

Therefore, when the plasma is regarded as the ground, the potential difference between the plasma and the first ring 112a decreases as the first ring 112a is raised more, and therefore the thickness of the sheath decreases. Specifically, as a result of lifting of the first ring 112a, the raised amount of the upper surface of the first ring 112a is greater than the reduction in the thickness of the sheath immediately above the first ring 112a, and therefore the height position of the sheath S immediately above the first ring 112a becomes lower. As a result, when the bias RF power of 400 kHz is applied, as the first ring 112a is raised higher, ions are incident in the edge region of the substrate W with the inward inclination as illustrated by the arrows of FIG. 2D.

Accordingly, when the bias RF power of 400 kHz is applied, a method of adjusting the potential of the first ring 112a and the second ring 112b to be the same or reducing the potential difference before and after the lifting of the first ring 112a is used in order to control the incident angle of ions to incline in the outer direction through lifting of the first ring 112a.

FIGS. 3A and 3B are diagrams for explaining the relationship between the incident angle of ions and the shape of the edge ring in one example of the operation of the edge ring. When the bias RF power of 400 kHz is applied, the shape of the second ring 112b is optimized so that the capacitance between the first ring 112a and the second ring 112b′ is constant. Therefore, before and after the lifting of the first ring 112a, the potential of the first ring 112a and the potential of the second ring 112b are adjusted to be the same or to reduce the potential difference so that ions are incident with the outward inclination as the first ring 112a is raised more. Thus, it is possible to control the incident angle of ions with the lifting of the first ring 112a. In this case, however, the second ring 112b′ is processed to have a specific shape for allowing the capacitance between the first ring 112a and the second ring 112b′ to be constant, which increases the number of components and complicates the structure of the edge ring.

In addition, it is important to obtain a vertical etching shape at high speed even in the edge region of the substrate W to etch a deep hole. Specifically, it is important that the incident angle of ions is controlled to be vertical in the edge region and etching is performed using ions having high ionic energy at a high etching rate. For example, the incident angle of ions is preferably controlled to stay within a range of ±0.2 degrees in the radial direction, when the vertical direction of the substrate W is determined as 90 degrees, i.e., in the range of 89.8 degrees to 90.2 degrees.

In contrast to the RF power having a frequency of 13 MHz, the RF power having a low frequency, such as 400 kHz, enables etching with high ion energy and enables processing of a deep hole having a vertical etching shape at high speed.

However, plasma etching using the RF power having a low frequency, such as 400 kHz, consumes the edge ring quickly, and the incident angle of ions in the edge region of the substrate W tends to be inclined inward. In addition, the service life of the edge ring is shortened, and a replacement cycle of the edge ring is likely to be shortened.

Accordingly, the edge ring according to one embodiment is divided into two parts, i.e., an upper part and a lower part, and the first ring 112a, which is the divided upper part and is disposed on the periphery of the substrate W, is driven up and down using the lifter 50. The second ring 112b, which is the divided lower part, is fixed. Therefore, when the edge ring is consumed by plasma etching using the RF power having a low frequency, such as 400 kHz, only the first ring 112a is replaced as a replacement target, thereby reducing the cost.

### Edge Ring Control Method

In an edge ring control method according to one embodiment, when bias RF power having a frequency of 13 MHz or higher is applied to the substrate support 11, as the countermeasure of the inward inclination of the incident angle of ions, the first ring 112a is controlled to be raised based on the consumption of the first ring 112a. Thus, the inclination of the incident angle of ions is controlled to be shifted from the inward to the outward (see FIG. 2B). Therefore, the replacement cycle of the edge ring can be extended. When the bias RF power having a frequency of 13 MHz or higher is applied to the substrate support 11, the initial position of the first ring 112a is the lowest position of the first ring 112a, as illustrated in FIG. 2A.

When the bias RF power having a frequency of 400 kHz is applied, on the other hand, as the countermeasure of the inward inclination of the ion incident angle, the first ring 112a is controlled to be raised based on the consumption of the first ring 112a, and as a result, the incident angle of ions is inclined further inward (see FIG. 2D). Thus, the incident angle of ions cannot be controlled to be substantially vertical.

Therefore, in the edge ring control method according to one embodiment, when the bias RF power having a frequency of 400 kHz is applied, as the countermeasure of the inward inclination of the ion incident angle, the first ring 112a is controlled to be lowered according to the consumption of the first ring 112a. Thus, the inclination of the incident angle of ions is controlled to be shifted from the inward to the outward. Therefore, it is possible to control the incident angle of ions to be substantially vertical by controlling the lowering position of the first ring 112a. As a result, the replacement cycle of the edge ring can be extended.

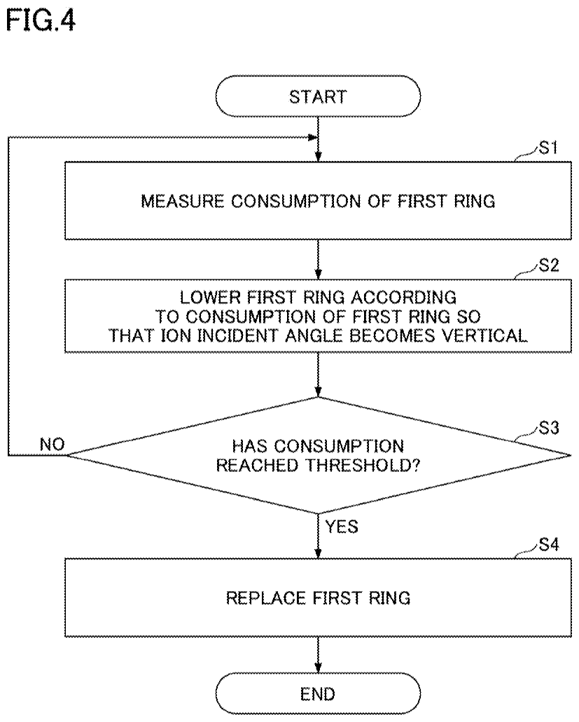

Hereinafter, the control method for the edge ring, which is divided into the first ring 112a and the second ring 112b, will be described with reference to FIGS. 4, 5A, and 5B. FIG. 4 is a flowchart illustrating one example of the edge ring control method according to one embodiment in which bias RF power having a frequency of 400 kHz is applied to the substrate support 11. FIGS. 5A and 5B are diagrams for explaining the edge ring control method according to one embodiment, in which the bias RF power having a frequency of 400 kHz is applied to the substrate support 11. When the bias RF power having a frequency of 13 MHz or higher is applied to the substrate support 11, the controller 2 performs the control of lifting the edge ring based on the consumption of the first ring 112a as illustrated in FIGS. 2A and 2B.

The edge ring control method according to one embodiment illustrated in FIG. 4 is controlled by the controller 2 and is executed by the plasma processing apparatus 1. In the plasma processing apparatus 1, the first ring 112a is exposed to plasma during plasma processing of a substrate W, and is consumed. The first ring 112a is arranged at a position (initial position) where the first ring 112a is raised to a preset height with respect to a surface facing the first ring 112a. As illustrated in FIG. 5A, in the initial state, the first ring 112a is raised to the highest position by the support pins 51. Specifically, the initial position of the first ring 112a is set to the maximum height of the first ring 112a at which the incident angle of ions in the edge region of the substrate W is controlled to be substantially vertical. In the edge ring control method according to one embodiment, lowering of the first ring 112a is started from the initial position. The surface facing the first ring 112a is the bottom surface 112b1 of the recess of the second ring 112b illustrated in FIGS. 5A and 5B. In the case where the edge ring is not divided, the surface facing the edge ring is the ring support surface of the electrostatic chuck 1111.

When the present process is started, the controller 2 performs the control to measure the consumption of the first ring 112a in step S1. During processing of the substrate W, the first ring 112a is consumed by the plasma. The controller 2 enables direct or indirect measurement of the consumption of the first ring 112a. As one example of the measuring method, the controller 2 may be configured to apply light in the thickness direction of the first ring 112a, and measure the thickness of the first ring 112a based on interference light of the first reflection light reflected from the surface of the first ring 112a and the second reflection light reflected from the back surface of the first ring 112a. The consumption of the first ring 112a can be calculated from the measurement result. In this case, the controller 2 may be configured to measure the consumption of the first ring 112a every time the preset number of substrates W are processed. The measuring method for the thickness of the first ring 112a is not limited to the above method, and any known methods can be used.

Without directly measuring the consumption of the first ring 112a, first correlation information may be acquired in advance by measurement, and may be stored in the memory 2a2. The first correlation information is correlation information between the consumption or thickness of the first ring 112a measured in advance and the application time of the source RF power that indicates the time-period in which the first ring 112a is exposed to plasma. In this case, in step S1, the controller 2 may calculate the consumption of the first ring 112a based on the total application time of the source RF power from the time when the first ring 112a is freshly disposed or replaced, with reference to the first correlation information stored in the memory 2a2. However, the measuring method for the consumption of the first ring 112a is not limited to the above method.

Next, in step S2, the controller 2 causes the first ring 112a to be lowered based on the consumption of the first ring 112a. In this step, the lowering position of the first ring 112a is controlled based on the consumption of the first ring 112a so that the incident angle of ions included in the plasma incident in the edge region of the substrate W becomes substantially vertical.

For example, the controller 2 may be configured to acquire second correlation information by measurement in advance, and store the second correlation information in the memory 2a2. The second correlation information is correlation information between the consumption of the first ring 112a, the height of the first ring 112a from the bottom surface 112b1 of the recess of the second ring 112b facing the first ring 112a, and the incident angle of ions. Then, in step S2, the controller 2 may control the lowering position of the first ring 112a based on the consumption of the first ring 112a with reference to the second correlation information stored in the memory 2a2 so that the incident angle of ions becomes substantially vertical.

In step S2, the controller 2 causes the first ring 112a to be lowered downward as the consumption of the first ring 112a increases. By gradually lowering the first ring 112a according to the consumption of the first ring 112a to counter the inward inclination of the incident angle of ions, the inclination of the incident angle of ions can be controlled to be shifted from the inward to the outward. Therefore, the incident angle of ions can be controlled to be substantially vertical by controlling the lowering position of the first ring 112a. As a result, the replacement cycle of the edge ring can be extended.

In the case where the bias RF power of 400 kHz is applied, the impedance due to the gap D is larger than, for example, the impedance when the bias RF power of 13 MHz is applied. Therefore, as the first ring 112a is lowered, the change in the potential of the first ring 112a increases, and the gap D is narrowed to reduce the impedance, with respect to the potential of the first ring 112a in the initial state of FIG. 5A. As a result, the potential of the first ring 112a becomes higher than the potential of the first ring 112a at the initial position of FIG. 5A.

The thickness of the sheath is determined by the potential difference between plasma and the edge ring. As the potential difference between the plasma and the edge ring increases, the thickness of the sheath increases. Therefore, when the plasma is regarded as the ground, as the first ring 112a is lowered from the state of FIG. 5A to the state of FIG. 5B, the potential difference between the plasma and the first ring 112a increases, and the thickness of the sheath increases. Specifically, as a result of the lowering of the first ring 112a, the height position of the sheath immediately above the first ring 112a becomes high because the increase in the thickness of the sheath immediately above the first ring 112a is greater than the lowered amount of the upper surface of the first ring 112a. As a result, when the bias RF power of 400 kHz is applied, incidence of ion can be oriented more outward (in the outer direction) as the first ring 112a is lowered as illustrated by the arrows of FIG. 5B.

When the first ring 112a is consumed, the sheath S immediately above the substrate W drops down. As the sheath S drops down, the incident angle of ions is inclined inward. Therefore, the height of the first ring 112a is lowered according to the consumption of the first ring 112a. As a result, the sheath S is raised, and the incident angle of ions is controlled to be shifted to the outward. Thus, the incident angle of ions can be controlled to be substantially vertical by the lowering position of the first ring 112a. According to the above control, the incident angle of ions can be controlled to be substantially vertical even when the bias RF power having a frequency of 400 kHz is applied.

In step S2, the controller 2 causes the first ring 112a to be lowered while controlling the first ring 112a not to be in contact with the second ring 112b. Then, the lowering of the first ring 112a is stopped before the first ring 112a is brought into contact with the bottom surface 112b1 of the recess of the second ring 112b. Therefore, a sudden change of the potential of the first ring 112a due to the contact between the first ring 112a and the second ring 112b and reduction in controllability (control precision) of the incident angle of ions can be avoided. However, in the case where the first ring 112a is formed of a dielectric material, such as quartz, the first ring 112a may be allowed to be in contact with the second ring 112b.

Next, in step S3, the controller 2 is configured to determine whether the consumption of the first ring 112a has reached a preset threshold. When the consumption of the first ring 112a is determined as not reaching the threshold, the controller 2 returns the process back to step S1, executes steps S1 and S2 to lower the first ring 112a based on the consumption of the first ring 112a.

In step S3, when the controller 2 determines that the consumption of the first ring 112a has reached the threshold, the controller 2 proceeds the process to step S4 to replace the first ring 112a, and ends the present process. For example, the threshold may be determined by measuring the minimum value of the thickness of the first ring 112a at which the incident angle of ions can be controlled to be substantially vertical when the first ring 112a is lowered.

### Experimental Result Example

Controllability of an incident angle of ions was compared using the plasma processing apparatus 1 between the control of the first ring 112a to be raised and the control of the first ring 112a to be lowered when source RF power was applied to the antenna 14 and bias RF power was applied to the substrate support 11 (the base 1110). For the control of the first ring 112a to be raised, the bias RF power having a frequency of 13 MHz was applied to the base 1110. For the control of the first ring 112a to be lowered, the bias RF power having a frequency of 400 kHz was applied to the base 1110.

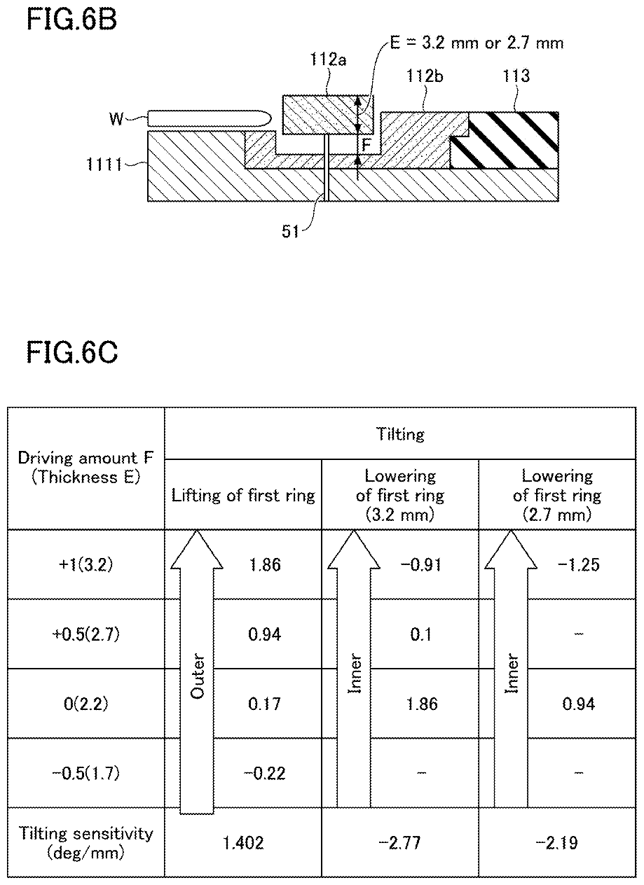

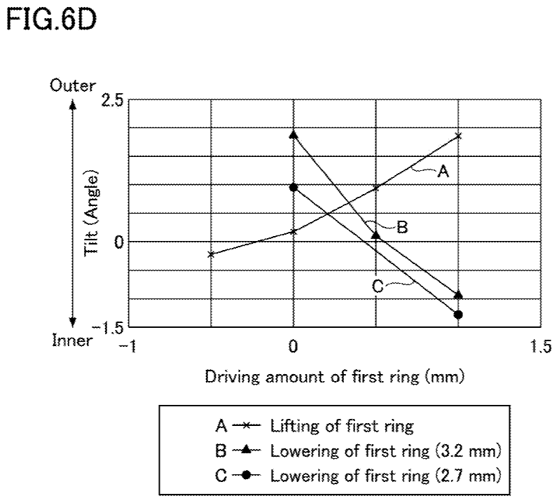

For the control of the first ring to be raised, an experiment was performed as the same operation as lifting the first ring by changing the thickness E of the first ring 112a′. As illustrated in FIG. 6A, a driving amount F of the first ring 112a′ was determined as 0 (i.e., no lifting of the first ring 112a′) when the thickness E of the first ring 112a′ was 2.2 mm. When the thickness E of the first ring 112a′ was 2.7 mm and 3.2 mm, the driving amount F of the first ring 112a′ was determined as +0.5 and +1.0, respectively. In addition, when the thickness E of the first ring 112a′ was 1.7 mm, the driving amount F of the first ring 112a′ was determined as −0.5. The lifting or lowering the height of the first ring 112a′ was controlled using the thickness E of the first ring 112a′ by changing the thickness E of the first ring 112a′ to 1.7 mm, 2.2 mm, 2.7 mm, or 3.2 mm.

For the control of lowering the first ring, two types of the first ring 112a, the first rings 112a having the thickness E of 3.2 mm and 2.7 mm, respectively, were prepared, and the first ring 112a having each thickness was actually raised by the support pins 51 with the driving amount F being changed by 0.5 mm, as illustrated in FIG. 6B.

In FIGS. 6C and 6D, the state in which the ion incident angle (tilting or tilt) is inclined outward (in the outer direction) is indicated by plus, and the state in which the ion incident angle is inclined inward (in the inner direction) is indicated by minus. In FIG. 6D, the horizontal axis represents the driving amount of the first rings 112a′ and 112a, and the vertical axis represents the ion incident angle.

When the driving amount F was 0 mm (the thickness of 2.2 mm), the ion incident angle was inclined by 1.86 degrees outward (in the outer direction) with the first ring 112a having the thickness of 3.2 mm. When the driving amount F was 1 mm (the thickness of 3.2 mm), the ion incident angle was inclined by −0.91 inward (in the inner direction) with the first ring 112a having the thickness of 3.2 mm. It was found from the above results that the ion incident angle could be controlled to be shifted from the outer direction to the inner direction by lifting the first ring 112a having the thickness of 3.2 mm.

Similarly, it was found that the ion incident direction could be controlled to be shifted from the outer direction to the inner direction by lifting the first ring 112a having the thickness of 2.7 mm. In other words, it was found that the ion incident angle was controlled to be shifted from the inner direction to the outer direction by lowering the first ring 112a when the first ring 112a had the thickness of 3.2 mm or 2.7 mm.

Next, when the driving amount F was changed from 0 mm to 1 mm with the first ring 112a having the thickness of 3.2 mm, the tilting (ion incident angle) sensitivity was 2.77 (degrees/mm), and the ion incident angle was shifted in the inner direction.

On the other hand, when the driving amount F was changed from 0 mm to 1 mm with the first ring 112a having the thickness of 2.7 mm, the tilting (ion incident angle) sensitivity was 2.19 (degrees/mm), and the ion incident angle was shifted in the inner direction. In other words, it was found from the first rings 112a having the thickness of 3.2 mm and 2.7 mm, respectively, that as the thickness of the first ring 112a increased, the tilting (ion incident angle) sensitivity increased, when the first ring 112a was lowered by the same driving amount.

The distance between the first ring 112a and the plasma relates to the driving amount of the first ring 112a and the thickness of first ring 112a. As the thickness of the first ring 112a increases, the sheath S is raised more. As a result, it is assumed that as the thickness of the first ring 112a increases, the controllable angle increases, which increases the sensitivity, thereby increasing controllability of the ion incident angle.

When the thickness of the first ring 112a′ of FIG. 6A was increased, the ion incident angle was shifted by 1.69 degrees in the outer direction by changing the driving amount F from 0 mm to 1 mm (in the actual experiment, the thickness of the first ring 112a′ was increased from 2.2 mm to 3.2 mm). In addition, when the thickness of the first ring 112a′ was increased from 1.7 mm to 3.2 mm, the sensitivity of the ion incident angle was 1.402 (degrees/mm). It was found from the above experiment result that the sensitivity of the ion incident angle was higher when the first ring 112a was lowered, compared to when the first ring 112a was raised.

In addition, when the first ring 112a was lowered, as illustrated in FIG. 6D, the line B and the line C representing the ion incident angle (tilt) when the first rings 112a having the 3.2 mm and 2.7 mm were lowered, respectively, indicated that the ion incident angle could be controlled to be shifted from the inner direction to the outer direction. When “the first ring 112a was lowered”, the driving amount of the first ring 112a on the horizontal axis of FIG. 6D is changed from the state of plus to the state of 0.

On the other hand, when the first ring 112a′ was raised, the line A representing the ion incident angle (tilt) when the first ring 112a′ was raised indicated that the ion incident angle could be controlled to be shifted from the inner direction to the outer direction. When “the first ring 112a′ was raised”, the driving amount of the first ring 112a′ on the horizontal axis of FIG. 6D is changed from the state of 0 to the state of plus.

### Effect Example

In the edge ring control method according to the present embodiment, the first ring 112a is lifted to an initial position that is set at a preset height, and the first ring 112a is lowered according to consumption of the first ring 112a. Thus, in a low frequency process using bias RF power having a frequency of lower than 13 MHz, an incident angle of ions incident in an edge region can be controlled with high sensitivity by using the same component configuration used in a high frequency process using bias RF power having a frequency of 13 MHz or higher.

In addition, it is possible to simplify the configuration and reduce the number of components of the apparatus, when control of the ion incident angle is performed in a low frequency process. Further, by adjusting only the thickness of the ring capable of being raised and lowered within the edge ring in advance, the ion incident angle can be controlled to be vertical, and a vertical etching shape can be obtained in an edge region of a substrate W. In addition, the ring capable of being raised and lowered can endure plasma etching for a long time in terms of consumption, and the replacement cycle of the ring capable of being raised and lowered can be extended. In this case, the thickness of the ring capable of being raised and lowered is adjusted to be higher than the height of the upper surface of the substrate W, and the ion incident angle may be slightly inclined in the outer direction in the state in which the driving amount by the lifter 50 is 0 mm.

The embodiments disclosed heretofore includes, for example, the following.

(E 1) A plasma processing apparatus, comprising:
a plasma-processing chamber;
a substrate support that is disposed inside the plasma-processing chamber and includes a main body including a central region configured to support a substrate and an annular region surrounding the central region;
an edge ring disposed on the annular region of the main body of the substrate support;
a lifter that includes two or more support pins and an actuator, and is configured to lift and lower the edge ring; and
a controller including a memory and a processor coupled to the memory,
wherein the memory contains instructions, which when executed by the processor, cause the plasma processing apparatus to perform a process including:
measuring consumption of the edge ring; and
controlling the lifter to lower the edge ring based on the consumption of the edge ring.

(E 2) The plasma processing apparatus according to (E 1), further comprising:
a bias RF power supply configured to apply bias RF power having a frequency of lower than 13 MHz to the substrate support.

(E 3) The plasma processing apparatus according to (E 2),
wherein the bias RF power supply configured to apply the bias RF power having the frequency of 100 kHz or higher and lower than 13 MHz to the substrate support.

(E 4) The plasma processing apparatus according to any one of (E 1) to (E 3), further comprising:
a source RF power supply configured to apply source RF power having a frequency of 13 MHz or higher to (i) an antenna disposed at an upper portion of or above the plasma-processing chamber, (ii) an upper electrode, or (iii) the substrate support.

(E 5) The plasma processing apparatus according to any one of (E 1) to (E 4),
wherein the processor causes the lifter to lower the edge ring based on the consumption of the edge ring so that an incident angle of ions incident in an edge region of the substrate is substantially vertical.

(E 6) The plasma processing apparatus according to any one of (E 1) to (E 5),
wherein the controller causes the lifter to start the lowering of the edge ring from an initial position of the edge ring, the initial position of the edge ring being a position at which the edge ring is lifted to a preset height.

(E 7) The plasma processing apparatus according to (E 6),
wherein the initial position of the edge ring is a maximum height of the edge ring at which an incident angle of ions incident in the edge region of the substrate is substantially vertical with the edge ring being not consumed.

(E 8) The plasma processing apparatus according to any one of (E 1) to (E 7),
wherein the controller causes the plasma processing apparatus to perform a process including:
measuring and acquiring correlation information between consumption of the edge ring, a height of the edge ring lifted, and an incident angle of ions incident in the edge region of the substrate in advance of the controlling of the lifter, and storing the correlation information in the memory, and
the controller causes the lifter to lower the edge ring based on the consumption of the edge ring with reference to the memory so that the incident angle of ions is substantially vertical.

(E 9) The plasma processing apparatus according to any one of (E 1) to (E 8),
wherein the edge ring includes a first ring that is capable of being lifted and lowered, and a second ring that supports the first ring, and
the controller causes the lifter to lower the first ring based on consumption of the first ring.

(E 10) The plasma processing apparatus according to (E 9),
wherein the controller causes the plasma processing apparatus to perform a process including:
determining whether or not the consumption of the first ring has reached a preset threshold, and
wherein, when the consumption of the first ring is determined as not reaching the preset threshold, the controller causes the lifter to lower the first ring based on the consumption of the first ring, and
when the consumption of the first ring is determined as reaching the preset threshold, the controller causes the plasma processing apparatus to execute a process of replacing the first ring.

(E 11) The plasma processing apparatus according to (E 9) or (E 10),
wherein the controller causes the lifter to lower the first ring while controlling the first ring not to be in contact with the second ring.

(E 12) The plasma processing apparatus according to any one of (E 9) to (E 11).
wherein the controller causes the plasma processing apparatus to execute a process of ending lowering of the edge ring before the first ring is brought into contact with a bottom surface of a recess of the second ring, where the recess of the second ring faces the first ring.

(E 13) The plasma processing apparatus according to (E 2),
wherein the substrate support includes a base and an electrostatic chuck, the electrostatic chuck including a substrate support surface that supports the substrate and a ring support surface on which the edge ring is mounted, and
the bias RF power is supplied to the base.

(E 14) A method of controlling an edge ring in a plasma processing apparatus including a plasma-processing chamber, a substrate support that is disposed inside the plasma-processing chamber and includes a main body including a central region configured to support a substrate and an annular region surrounding the central region, the edge ring that is disposed on the annulare region of the main body of the substrate support, and a lifter configured to lift and lower the edge ring, the method comprising:
measuring consumption of the edge ring; and
causing the lifter to lower the edge ring based on the consumption of the edge ring.

(E 15) The method according to (E 14),
wherein the causing the lifter to lower includes causing the lifter to lower the edge ring based on the consumption of the edge ring so that an incident angle of ions incident in an edge region of the substrate is substantially vertical.

(E 16) The method according to (E 14) or (E 15),
wherein the causing the lifter to lower includes causing the lifter to start the lowering of the edge ring from an initial position of the edge ring, the initial position of the edge ring being a position at which the edge ring is lifted to a preset height.

(E 17) The method according to (E 16),
wherein the initial position of the edge ring is a maximum height of the edge ring at which an incident angle of ions incident in the edge region of the substrate is substantially vertical with the edge ring being not consumed.

(E 18) The method according to any one of (E 14) to (E 17), further comprising: measuring and acquiring correlation information between consumption of the edge ring, a height of the edge ring lifted, and an incident angle of ions incident in the edge region of the substrate in advance of the controlling of the lifter, and storing the correlation information in the memory,
wherein the causing the lifter to lower includes causing the lifter to lower the edge ring based on the consumption of the edge ring with reference to the memory so that the incident angle of ions is substantially vertical.

(E 19) The method according to any one of (E 14) to (E 18),
wherein the edge ring includes a first ring that is capable of being lifted and lowered, and a second ring that supports the first ring, and
the causing the lifter to lower includes causing the lifter to lower the first ring based on consumption of the first ring.

(E 20) The method according to (E 19), further comprising:
determining whether or not the consumption of the first ring has reached a preset threshold,
wherein, when the consumption of the first ring is determined as not reaching the preset threshold, causing the lifter to lower the first ring based on the consumption of the first ring, and
when the consumption of the first ring is determined as reaching the preset threshold, replacing the first ring.

While certain embodiments have been described, these embodiments have been presented by way of example only, and are not intended to limit the scope of the disclosures, Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

For example, in the above embodiments, the inductively coupled plasma processing apparatus has been described as an example, but the present disclosure is not limited to the inductively coupled plasma processing apparatus, and may be applied to other plasma processing apparatuses. For example, instead of the inductively coupled plasma processing apparatus, a capacitively-coupled plasma (CCP) processing apparatus may be used. In this case, the CCP processing apparatus includes an upper electrode and a lower electrode facing each other. The lower electrode is disposed within the substrate support and the upper electrode is disposed at the upper portion of the process chamber. Accordingly, the RF generator is coupled to the upper electrode of the CCP processing device or the antenna of the inductively coupled plasma processing device. Specifically, the RF generator is coupled to the plasma-processing chamber 10.

What is claimed is:

1. A plasma processing apparatus, comprising:
a plasma-processing chamber;
a substrate support that is disposed inside the plasma-processing chamber and includes a main body including a central region configured to support a substrate and an annular region surrounding the central region;
an edge ring disposed on the annular region of the main body of the substrate support;
a lifter that includes two or more support pins and an actuator, and is configured to lift and lower the edge ring; and
a controller including a memory and a processor coupled to the memory,
wherein the memory contains instructions, which when executed by the processor, cause the plasma processing apparatus to perform a process including:
measuring consumption of the edge ring; and
controlling the lifter to lower the edge ring based on the consumption of the edge ring.

2. The plasma processing apparatus according to claim 1, further comprising:
a bias RF power supply configured to apply bias RF power having a frequency of lower than 13 MHz to the substrate support.

3. The plasma processing apparatus according to claim 2,
wherein the bias RF power supply configured to apply the bias RF power having the frequency of 100 kHz or higher and lower than 13 MHz to the substrate support.

4. The plasma processing apparatus according to claim 2, further comprising:
a source RF power supply configured to apply source RF power having a frequency of 13 MHz or higher to (i) an antenna disposed at an upper portion of or above the plasma-processing chamber, (ii) an upper electrode, or (iii) the substrate support.

5. The plasma processing apparatus according to claim 1,
wherein the controller causes the lifter to lower the edge ring based on the consumption of the edge ring so that an incident angle of ions incident in an edge region of the substrate is substantially vertical.

6. The plasma processing apparatus according to claim 1,
wherein the controller causes the lifter to start the lowering of the edge ring from an initial position of the edge ring, the initial position of the edge ring being a position at which the edge ring is lifted to a preset height.

7. The plasma processing apparatus according to claim 6,
wherein the initial position of the edge ring is a maximum height of the edge ring at which an incident angle of ions incident in the edge region of the substrate is substantially vertical with the edge ring being not consumed.

8. The plasma processing apparatus according to claim 1,
wherein the controller causes the plasma processing apparatus to perform a process including:
measuring and acquiring correlation information between consumption of the edge ring, a height of the edge ring lifted, and an incident angle of ions incident in the edge region of the substrate in advance of the controlling of the lifter, and storing the correlation information in the memory, and
the controller causes the lifter to lower the edge ring based on the consumption of the edge ring with reference to the memory so that the incident angle of ions is substantially vertical.

9. The plasma processing apparatus according to claim 1,
wherein the edge ring includes a first ring that is capable of being lifted and lowered, and a second ring that supports the first ring, and
the controller causes the lifter to lower the first ring based on consumption of the first ring.

10. The plasma processing apparatus according to claim 9,
wherein the controller causes the plasma processing apparatus to perform a process including:
determining whether or not the consumption of the first ring has reached a preset threshold, and
wherein, when the consumption of the first ring is determined as not reaching the preset threshold, the controller causes the lifter to lower the first ring based on the consumption of the first ring, and
when the consumption of the first ring is determined as reaching the preset threshold, the controller causes the plasma processing apparatus to execute a process of replacing the first ring.

11. The plasma processing apparatus according to claim 9, wherein the controller causes the lifter to lower the first ring while controlling the first ring not to be in contact with the second ring.

12. The plasma processing apparatus according to claim 9,
wherein the controller causes the plasma processing apparatus to execute a process of ending lowering of the edge ring before the first ring is brought into contact with a bottom surface of a recess of the second ring, where the recess of the second ring faces the first ring.

13. The plasma processing apparatus according to claim 2,
wherein the substrate support includes a base and an electrostatic chuck, the electrostatic chuck including a substrate support surface that supports the substrate and a ring support surface on which the edge ring is mounted, and
the bias RF power is supplied to the base.

14. A method of controlling an edge ring in a plasma processing apparatus including a plasma-processing chamber, a substrate support that is disposed inside the plasma-processing chamber and includes a main body including a central region configured to support a substrate and an annular region surrounding the central region, the edge ring that is disposed on the annulare region of the main body of the substrate support, and a lifter that lifts and lowers the edge ring, the method comprising:
measuring consumption of the edge ring; and
causing the lifter to lower the edge ring based on the consumption of the edge ring.

15. The method according to claim 14,
wherein the causing the lifter to lower includes causing the lifter to lower the edge ring based on the consumption of the edge ring so that an incident angle of ions incident in an edge region of the substrate is substantially vertical.

16. The method according to claim 14,
wherein the causing the lifter to lower includes causing the lifter to start the lowering of the edge ring from an initial position of the edge ring, the initial position of the edge ring being a position at which the edge ring is lifted to a preset height.

17. The method according to claim 16,
wherein the initial position of the edge ring is a maximum height of the edge ring at which an incident angle of ions incident in the edge region of the substrate is substantially vertical with the edge ring being not consumed.

18. The method according to claim 14, further comprising:
measuring and acquiring correlation information between consumption of the edge ring, a height of the edge ring lifted, and an incident angle of ions incident in the edge region of the substrate in advance of the controlling of the lifter, and storing the correlation information in the memory,
wherein the causing the lifter to lower includes causing the lifter to lower the edge ring based on the consumption of the edge ring with reference to the memory so that the incident angle of ions is substantially vertical.

19. The method according to claim 14,
wherein the edge ring includes a first ring that is capable of being lifted and lowered, and a second ring that supports the first ring, and
the causing the lifter to lower includes causing the lifter to lower the

20. The method according to claim 19, further comprising:
determining whether or not the consumption of the first ring has reached a preset threshold,
wherein, when the consumption of the first ring is determined as not reaching the preset threshold, causing the lifter to lower the first ring based on the consumption of the first ring, and
when the consumption of the first ring is determined as reaching the preset threshold, replacing the first ring.
